(19) United States
(12) Patent Application Publication
(10) Pub. No.: US 2026/0157147 A1
(43) Pub. Date: Jun. 4, 2026

(54) ELECTROLYTIC METHOD FOR CARRIER WAFER SEPARATION

(71) Applicant: Micron Technology, Inc., Boise, ID (US)

(72) Inventors: Matthew Thorum, Boise, ID (US); Farrell M. Good, Meridian, ID (US); Srinivasa Reddy Yeduru, Meridian, ID (US); Guohua Wei, Boise, ID (US); Gurtej S. Sandhu, Boise, ID (US)

(21) Appl. No.: 19/362,213

(22) Filed: Oct. 17, 2025

Related U.S. Application Data
(60) Provisional application No. 63/727,534, filed on Dec. 3, 2024.

(51) Int. Cl. H01L 21/683; H01L 23/48

(52) U.S. Cl. CPC H10P 72/74; H10W 20/20; H10P 72/7412; H10P 72/7438; H10P 72/744

(57) ABSTRACT

Electrolytic methods for carrier wafer separation are disclosed herein. In some embodiments, the method includes depositing a coating on a carrier wafer. The coating can include a first electrode layer, a second electrode layer, and a metal oxide layer between the first and second electrode layers. The method can further include attaching a device wafer to the coating, processing the device wafer, and applying a bias voltage to the first and second electrode layers. Applying the bias voltage can separate the device wafer from the carrier wafer.

### CROSS-REFERENCE TO RELATED APPLICATION(S)

The present application claims priority to U.S. Provisional Patent Application No. 63/727,534, filed Dec. 3, 2024, the disclosure of which is incorporated herein by reference in its entirety.

### TECHNICAL FIELD

The present disclosure generally relates to semiconductor device assemblies, and more particularly relates to electrolytic methods for carrier wafer separation.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIG. 1 is a partially schematic diagram of a semiconductor device manufacturing system.

FIG. 2 is a partially schematic diagram of a semiconductor device manufacturing system configured in accordance with embodiments of the present technology.

FIG. 3 is a partially schematic diagram of another semiconductor device manufacturing system configured in accordance with embodiments of the present technology.

FIG. 4 is an enlarged, partially schematic diagram of a coating configured in accordance with embodiments of the present technology.

FIG. 5 is an enlarged, partially schematic diagram of another coating configured in accordance with embodiments of the present technology.

FIG. 6 is an enlarged, partially schematic diagram of a semiconductor device manufacturing system after debonding and configured in accordance with embodiments of the present technology.

FIG. 7 is a partially schematic diagram of another semiconductor device manufacturing system configured in accordance with embodiments of the present technology.

FIG. 8 is a partially schematic diagram of another semiconductor device manufacturing system configured in accordance with embodiments of the present technology.

FIG. 9 is a flowchart illustrating a method for manufacturing a semiconductor device in accordance with embodiments of the present technology.

A person skilled in the relevant art will understand that the features shown in the drawings are for purposes of illustrations, and variations, including different and/or additional features and arrangements thereof, are possible.

### DETAILED DESCRIPTION

In some cases of semiconductor device manufacturing, particularly those involving thin wafer processing, backside processing, advanced interconnects, and 3D integration, carrier wafers are used to facilitate the handling and processing of delicate device wafers. Carrier wafers provide mechanical support and stability to device wafers bonded thereto during various steps for manufacturing a semiconductor device, such as thinning the device wafer or backside processing. Once the manufacturing steps are completed, the carrier wafers are typically destroyed while still bonded to the device wafers. This allows the semiconductor device to be further packaged without a carrier wafer attached thereto. However, destroying carrier wafers means that one or more new carrier wafers must be sacrificially used for each new device wafer, resulting in significant material and process costs.

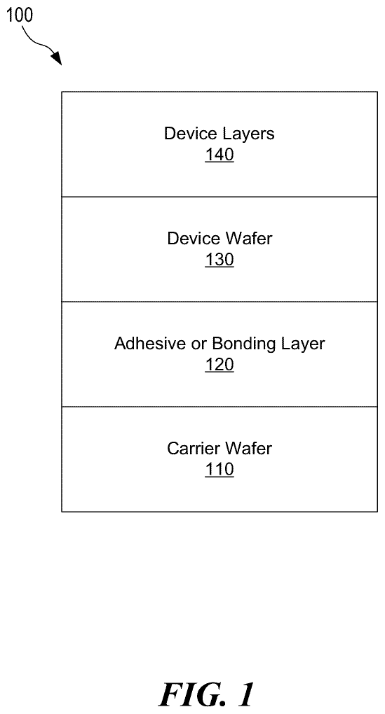

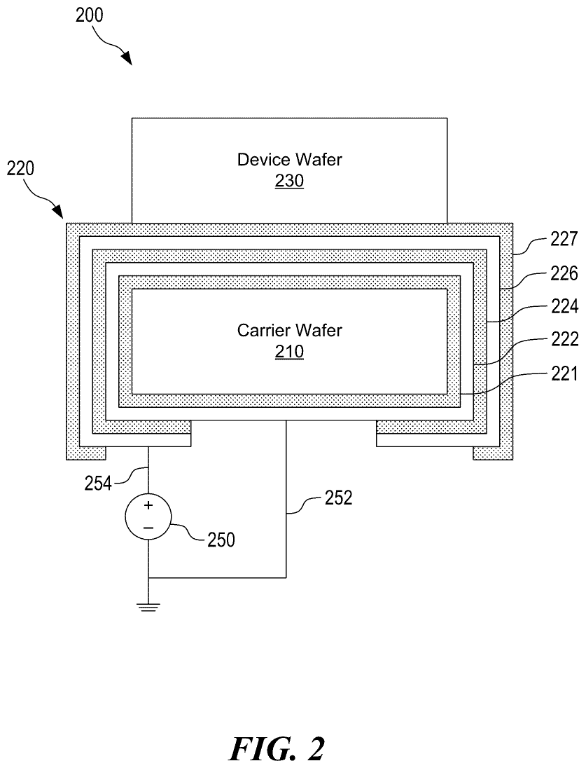

FIG. 1 is a partially schematic diagram of a semiconductor device manufacturing system 100 (“the system 100”). The system 100 includes a carrier wafer 110 and a device wafer 130 attached to the carrier wafer 110 via an adhesive or bonding layer 120. When manufacturing a semiconductor device, the carrier wafer 110 (e.g., a silicon wafer) can provide mechanical support and stability to the device wafer 130 as the device wafer 130 is subjected to various processing. For example, in some embodiments, the device wafer 130 undergoes various wafer processing steps including thinning, backside processing, patterning and etching, implantation and doping, and/or the like. In some embodiments, one or more device layers 140 are formed (e.g., deposited) on the side of the device wafer 130 opposite the carrier wafer 110. Once the processing of the device wafer 130 and/or formation of the one or more device layers 140 are completed, the carrier wafer 110 is destructively removed via back-grinding, etching, and/or the like. However, the sacrificial nature of the carrier wafer 110 requires a new carrier wafer to be used and destroyed for each device wafer. The material and process costs associated with using a new carrier wafer can be significant (e.g., about $80 per wafer). To address these problems and others, embodiments of the present technology provide a way to reuse carrier wafers, as illustrated in and discussed below with reference to FIGS. 2-7.

FIG. 2 is a partially schematic diagram of a semiconductor device manufacturing system 200 (“the system 200”) configured in accordance with embodiments of the present technology. The system 200 includes a carrier wafer 210, a coating 220 deposited on the carrier wafer 210, and a device wafer 230 attached to the coating 220. The carrier wafer 210 and/or the device wafer 230 can each comprise a silicon wafer. The coating 220 can be disposed between the carrier wafer 210 and the device wafer 230, and can include a plurality of layers, as shown.

In some embodiments, the coating 220 includes a first electrode layer 222, a second electrode layer 226, and a metal oxide layer 224. The first electrode layer 222 (also referred to as the bottom electrode layer) is disposed between the carrier wafer 210 and the metal oxide layer 224. The first electrode layer 222 can comprise tungsten (W), titanium nitride (TiN), titanium (Ti), and/or other suitable material. The second electrode layer (also referred to as the top electrode layer) is disposed between the device wafer 230 and the metal oxide layer 224. The second electrode layer 226 can comprise tungsten (W), ruthenium (Ru), carbon (C), and/or other suitable material. The metal oxide layer 224 is disposed between the first electrode layer 222 and the second electrode layer 226. The metal oxide layer 224 can comprise titanium dioxide (TiO₂), cerium dioxide (CeO₂), zirconium dioxide (ZrO₂), hafnium dioxide (HfO₂), hafnium silicate (HfSiOₓ), and/or other suitable material.

In some embodiments, the coating 220 further includes a first dielectric layer 221 and/or a second dielectric layer 227. The first dielectric layer 221 can be disposed between the carrier wafer 210 and the first electrode layer 222, and the second dielectric layer 227 can be disposed between the device wafer 230 and the second electrode layer 226. Each of the layers 221, 222, 224, 226, 227 of the coating 220 can be deposited (or otherwise formed) on the carrier wafer 210 via atomic layer deposition (ALD) and/or other suitable methods. The coating 220 can be deposited to cover an entirety or only a portion of the carrier wafer 210. In embodiments including the first dielectric layer 221 and/or the second dielectric layer 227, the coating 220 can be attached to the carrier wafer 210 and/or the device wafer 230 via dielectric-dielectric bonding. It is appreciated that the components illustrated in FIG. 2 are not drawn to scale. For example, the thickness of each of the carrier wafer 210 and the device wafer 230 can be on the scale of microns (m) while the thickness of each of the layers 221, 222, 224, 226, 227 of the coating 220 can be on the scale of nanometers (nm).

In FIG. 2, a voltage source 250 is electrically coupled to the coating 220 on the back side of the carrier wafer 210 (opposite the device wafer 230). More specifically, in the illustrated embodiment, portions of the coating 220 on the back side of the carrier wafer 210 are removed to expose the first electrode layer 222 and the second electrode layer 226, allowing a first lead 252 extending from the negative terminal of the voltage source 250 to couple to the first electrode layer 222 and a second lead 254 extending from the positive terminal of the voltage source 250 to couple to the second electrode layer 226. The first lead 252 can also be coupled to ground. In other embodiments, the first lead 252 and/or the second lead 254 can be coupled to the first electrode layer 222 and the second electrode layer 226, respectively, without removing portions of the coating 220. For example, the first lead 252 and/or the second lead 254 can have an insulating sleeve and be inserted directly into the coating 220.

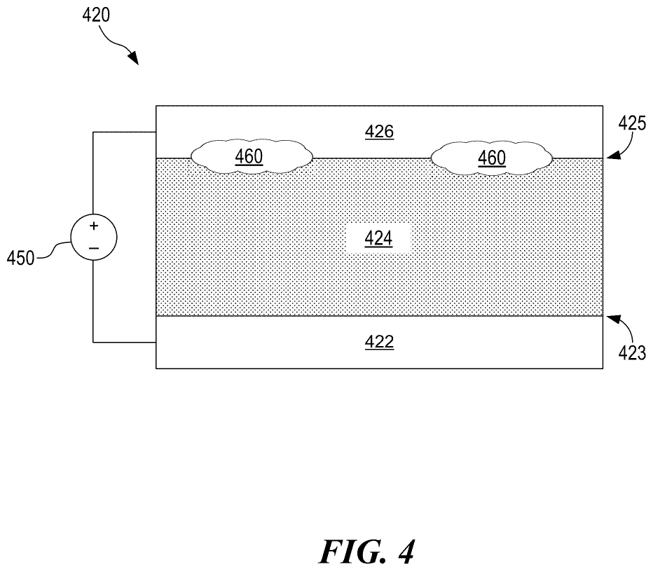

As discussed in further detail below with reference to FIGS. 4-6, the voltage source 250 can be operated to apply a bias voltage to the first electrode layer 222 and the second electrode layer 226. Application of the bias voltage can cause the second electrode layer 226 to separate from the metal oxide layer 224, thereby separating the device wafer 230 from the carrier wafer 210. In some embodiments, the voltage source 250 is electrically coupled to the coating 220 only once the system 200 is ready for this debonding step. Therefore, the device wafer 230, and thus the rest of the semiconductor device manufactured, can be free of the carrier wafer 210 without the need to destructively remove the carrier wafer 210. By keeping the carrier wafer 210 during the debonding process, the carrier wafer 210 can be reused in the manufacture of additional semiconductor devices. This can directly result in material, process, and associated cost savings.

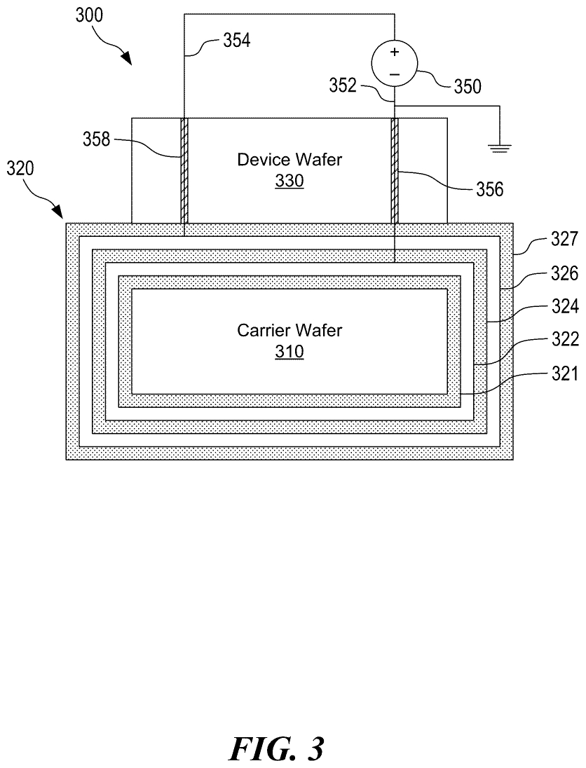

FIG. 3 is a partially schematic diagram of another semiconductor device manufacturing system 300 (“the system 300”) configured in accordance with embodiments of the present technology. The system 300 can be generally similar to the system 200 of FIG. 2. For example, the system 300 includes a carrier wafer 310, a coating 320 deposited on the carrier wafer 310, and a device wafer 330 attached to the coating 320. The coating 320 can be disposed between the carrier wafer 310 and the device wafer 330, and can include a plurality of layers including a first electrode layer 322, a second electrode layer 326, a metal oxide layer 324 therebetween, and optionally a first dielectric layer 321 and/or a second dielectric layer 327. Also, a voltage source 350 can be electrically coupled to select layers of the coating 320 via a first lead 352 extending from the negative terminal of the voltage source 350 and a second lead 354 extending from the positive terminal of the voltage source 350. The first lead 352 can also be coupled to ground.

Unlike the system 200, however, the system 300 further includes a first through-silicon via (TSV) 356 and a second TSV 358 each extending through the device wafer 330. The first lead 352 can be electrically coupled to the first electrode layer 322 through or via the first TSV 356, and the second lead 354 can be electrically coupled to the second electrode layer 326 through or via the second TSV 358. In some embodiments, the portions of the leads extending through the layers of the coating 320 are insulated. Therefore, by including one or more TSVs, the system 300 avoids the need to remove portions of the coating 320 to expose certain layers thereof. As discussed in further detail below with reference to FIGS. 4-6, the voltage source 350 can be operated to apply a bias voltage to the first electrode layer 322 and the second electrode layer 326. The bias voltage applied can cause the second electrode layer 326 to separate from the metal oxide layer 324, thereby separating the device wafer 330 from the carrier wafer 310.

FIG. 4 is an enlarged, partially schematic diagram of a coating 420 configured in accordance with embodiments of the present technology. The coating 420 can be an example of the coating 220 of FIG. 2 or the coating 320 of FIG. 3. The optional dielectric layers are omitted for illustrative purposes. The coating 420 comprises a metal-insulator-metal (MIM) stack including a first electrode layer 422, a second electrode layer 426, and a metal oxide layer 424 therebetween. The first electrode layer 422 and the metal oxide layer 424 form a first interface 423 therebetween, and the second electrode layer 426 and the metal oxide layer 424 form a second interface 425 therebetween. A voltage source 450 can be electrically coupled to the first electrode layer 422 and the second electrode layer 426. More specifically, the negative terminal of the voltage source 450 can be electrically coupled to the first electrode layer 422 so that the first electrode layer 422 can act as a cathode, and the positive terminal of the voltage source 450 can be electrically coupled to the second electrode layer 426 so that the second electrode layer 426 can act as an anode.

As discussed above with reference to FIG. 2, each of the first electrode layer 422, the second electrode layer 426, and the metal oxide layer 424 can comprise one or more of various suitable materials. In particular, in some embodiments, the material for the metal oxide layer 424 is selected to have one or more of the following features: (i) non-zero oxide ion mobility (higher mobility may be preferred), (ii) reducible (able to undergo a chemical reduction reaction) at a practical (e.g., achievable) bias voltage level, (iii) low electron/hole conductivity to enable a sufficient bias voltage between the first electrode layer 422 and the second electrode layer 426, and (iv) compatible with the thermal budge requirements of the parts (e.g., withstand temperatures of 1000° C. or more and associated stress, provide sufficient adhesion).

When a bias voltage is applied to the first electrode layer 422 (the cathode) and the second electrode layer 426 (the anode), a portion of the metal oxide layer 424 at the first interface 423 undergoes a chemical reduction reaction to generate oxide ions. Equation 1 below is the generic chemical reduction reaction, wherein M represents a suitable metal element for the metal oxide layer 424. Equation 2 below is the chemical reduction reaction for titanium oxide, an example material for the metal oxide layer 424.

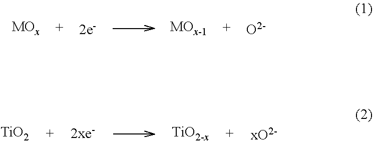

The generated oxide ions migrate from the first interface 423 to the second interface 425 (from the cathode to the anode) by virtue of the bias voltage applied. The oxide ions that reach the second interface 425 are then oxidized to oxygen gas 460 according to equation 3 below.

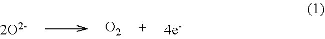

The oxygen gas 460 is formed (e.g., as bubbles) at the second interface 425, thereby separating the second electrode layer 426 from the metal oxide layer 424. For example, the oxygen gas 460 can cause delamination in the coating 420 at the second interface 425. Additionally or alternatively, the oxygen gas 460 can form a metal oxide interface with poor adhesion at the second interface 425. When the second electrode layer 426 separates from the metal oxide layer 424 at the second interface 425, the device wafer (not shown) therefore also separates from the carrier wafer (also not shown). Any portion of the coating 420 that has not been delaminated (e.g., away from the second interface 425) can easily be separated physically because the coating 420 itself is relatively thin (e.g., on the scale of nanometers).

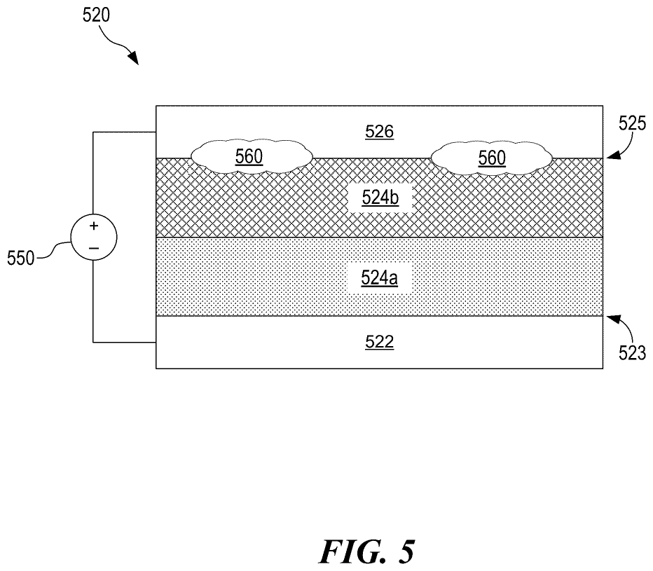

In some embodiments, oxygen vacancies formed during the oxidization reaction of Equation 3 above at the second interface 425 can coalesce and migrate from the second interface 425 to the first interface 423 (from the anode to the cathode). These oxygen vacancies can cause changes in the structure of the reduced metal oxide at the first interface 423 (e.g., MOₓ₋₁, TiO₂₋ₓ), and suboxide filaments can nucleate and grow from the first interface 423 to the second interface 425 as thread-like structures within the matrix of the metal oxide layer 424. These suboxide filaments can be conductive and can short-circuit the first electrode layer 422 and the second electrode layer 426 before sufficient delamination occurs. Therefore, in some embodiments, a coating includes an additional oxide layer, as illustrated in FIG. 5.

FIG. 5 is an enlarged, partially schematic diagram of a coating 520 configured in accordance with embodiments of the present technology. The coating 520 can be an example of the coating 220 of FIG. 2 or the coating 320 of FIG. 3. The optional dielectric layers are omitted for illustrative purposes. The coating 520 comprises a metal-insulator-insulator-metal (MIIM) stack including a first electrode layer 522, a second electrode layer 526, and a first metal oxide layer 524a and a second metal oxide layer 524b therebetween. The first electrode layer 522 and the first metal oxide layer 524a form a first interface 523 therebetween, and the second electrode layer 526 and the second metal oxide layer 524b form a second interface 525 therebetween. A voltage source 550 can be electrically coupled to the first electrode layer 522 and the second electrode layer 526. More specifically, the negative terminal of the voltage source 550 can be electrically coupled to the first electrode layer 522 so that the first electrode layer 522 can act as a cathode, and the positive terminal of the voltage source 550 can be electrically coupled to the second electrode layer 526 so that the second electrode layer 526 can act as an anode.

The first metal oxide layer 524a can be generally similar in material and function as the metal oxide layer 424 of FIG. 4. For example, the first metal oxide layer 524a can comprise titanium dioxide, cerium dioxide, zirconium dioxide, hafnium dioxide, hafnium silicate, and/or other suitable material. The portion of the first metal oxide layer 524a at the first interface 523 can undergo a chemical reduction reaction according to Equations 1 or 2 to generate oxide ions, which then migrate to the second interface 525 to be oxidized into oxygen gas 560. The second metal oxide layer 524b can have non-zero oxide ion mobility to allow the oxide ions to migrate from the first interface 523 to the second interface 525.

The second metal oxide layer 524b can comprise a non-reducible oxide such as aluminum oxide (Al₂O₃) or magnesium oxide (MgO). The non-reducible nature can allow the second metal oxide layer 524b, which is positioned between the first metal oxide layer 524a and the second electrode layer 526, to block, slow, or otherwise impede the growth of conductive suboxide filaments from reaching the second electrode layer 526. Therefore, the inclusion of two metal oxide layers 524a, 524b can reduce the risk of short-circuiting the electrode layers 522, 526 before proper debonding or delamination of the coating 520.

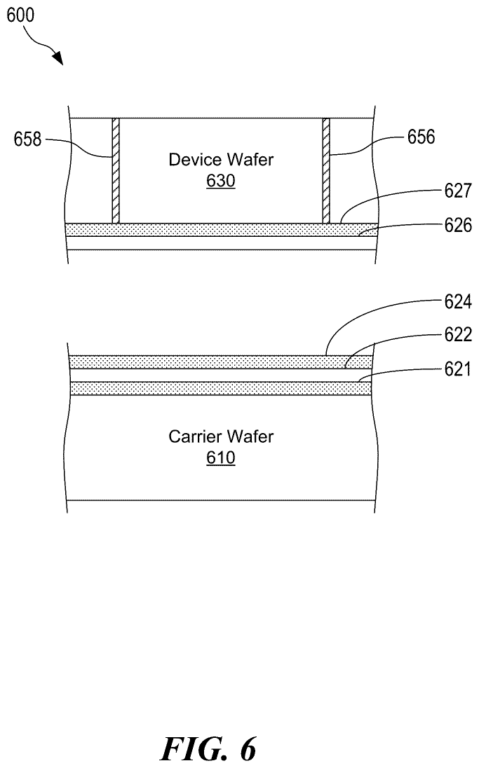

FIG. 6 is an enlarged, partially schematic diagram of a semiconductor device manufacturing system 600 after debonding or delamination, and configured in accordance with embodiments of the present technology. As discussed above with reference to FIGS. 4 and 5, the formation of oxygen gas can facilitate delamination of a coating. Subsequently, as illustrated in FIG. 6, a carrier wafer 610 is separated from a device wafer 630. Device layers on the device wafer 630 are omitted for illustrative purposes. A first dielectric layer 621 (optional), a first electrode layer 622, and a metal oxide layer 624 of the coating can remain attached to the carrier wafer 610 after delamination. In embodiments in which a coating with two metal oxide layers is used, the second metal oxide layer can also remain attached to the carrier wafer 610 after delamination. A second electrode layer 626 and a second dielectric layer 627 (optional) can remain with the device wafer 630.

The carrier wafer 610 can then be cleaned (e.g., have the remaining layers thereon removed) and/or otherwise processed for reuse. As previously mentioned, the use of a coating configured in accordance with embodiments of the present technology eliminates the need to destructively remove the carrier wafer 610 from the device wafer 630. This allows the carrier wafer 610 to be reused for additional device wafers, thus saving material and process costs associated with using and destroying a new carrier wafer for each device wafer to be processed.

The second electrode layer 626 and/or the second dielectric layer 627 can either remain on the device wafer 630 downstream (e.g., as part of the final semiconductor device) or removed off of the device wafer 630. In some cases, a portion of the second electrode layer 626 remaining on the device wafer 630 comprises remnants of the second electrode layer 626 after a removal process for removing the second electrode layer 626 from the device wafer 630. In some embodiments, one or more TSVs 656, 658 can remain in the device wafer 630 if the voltage source was electrically coupled to the coating at the front side of the carrier wafer 610.

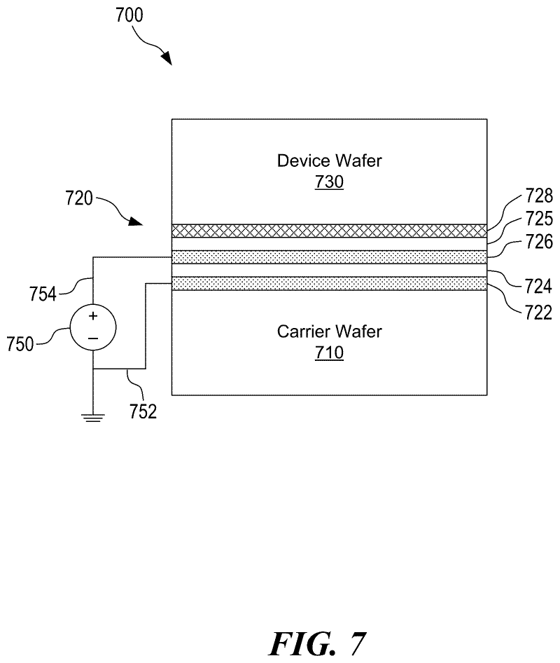

FIG. 7 is a partially schematic diagram of another semiconductor device manufacturing system 700 (“the system 700”) configured in accordance with embodiments of the present technology. The system 700 can be generally similar to the system 200 of FIG. 2. For example, the system 700 includes a carrier wafer 710, a coating 720 deposited on the carrier wafer 710, and a device wafer 730 attached to the coating 720. The coating 720 can be disposed between the carrier wafer 710 and the device wafer 730, and can include a plurality of layers including a first electrode layer 722, a second electrode layer 726, a dielectric layer 724 therebetween, a sacrificial layer 725, and optionally a heat-absorbing layer 728. In some embodiments, the coating 720 can further include one or more dielectric layers (e.g., the first dielectric layer 221, the second dielectric layer 227) coupled to the carrier wafer 710 and/or the device wafer 730.

Also, a voltage source 750 can be electrically coupled to select layers of the coating 720 via a first lead 752 extending from the negative terminal of the voltage source 750 and a second lead 754 extending from the positive terminal of the voltage source 750. In the illustrated embodiment, the first lead 752 is electrically coupled to the first electrode layer 722 and the second lead 754 is electrically coupled to the second electrode layer 726. The first lead 752 can also be coupled to ground.

In operation, the voltage source 750 can be operated to apply a bias voltage to the first electrode layer 722 and the second electrode layer 726, and application of the bias voltage can cause breakdown of the dielectric layer 724. The dielectric layer 724 can have one or more features that facilitate the breakdown. In some embodiments, the dielectric layer 724 can have defects. For example, the dielectric layer 724 can include low-temperature deposited SiO₂, low-temperature deposited SiN, and/or carbon-doped oxides and nitrides. Such compositions can lead to the formation of various types of dielectric defects. In some embodiments, the dielectric layer 724 can include a 2D dielectric material (e.g., extremely thin) that has a low dielectric strength.

Breaking down the dielectric layer 724 can generate a sufficient amount of heat to decompose the sacrificial layer 725. The heat can raise the temperature of the sacrificial layer 725 to at least 400° C., 600° C., 800° C., 1000° C., 1200° C., or more (e.g., about 500° C., about 1150° C.). In some embodiments, the sacrificial layer 725 can include a material with a relatively low melting point so that the sacrificial layer 725 melts away from the system 700. In some embodiments, the sacrificial layer 725 is doped with carbon and/or selenium. The heat-absorbing layer 728 can confine the heat generated by the breakdown of the dielectric layer 724 to the side of the heat-absorbing layer 728 with the sacrificial layer 725, and prevent (or at least impede) heat transfer to the device wafer 730.

Once the sacrificial layer 725 sufficiently melts away or otherwise decomposes (e.g., via large area void formation), the device wafer 730 (and the heat-absorbing layer 728 bonded thereto) and the carrier wafer 710 (and the first electrode layer 722, the second electrode layer 726, and the dielectric layer 724 therebetween bonded thereto) can be separated. One or more of the layers 722, 724, 726, 728 can be subsequently scrubbed or otherwise removed, or kept thereon. In some embodiments, the voltage source 750 is electrically coupled to the coating 720 only once the system 700 is ready for this debonding step.

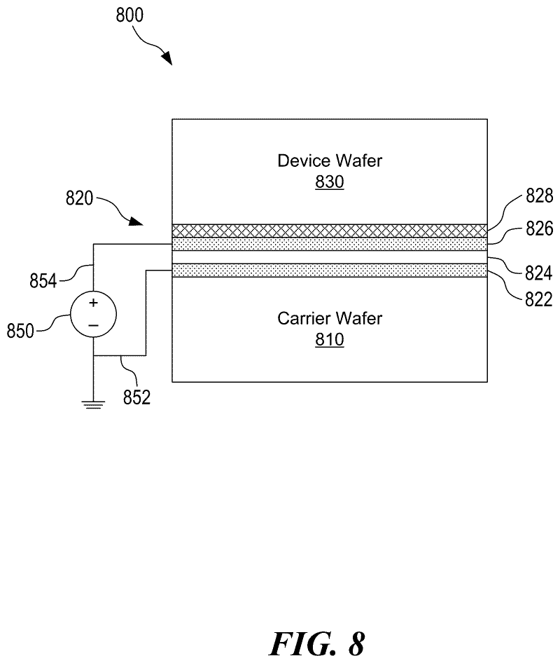

FIG. 8 is a partially schematic diagram of another semiconductor device manufacturing system 800 (“the system 800”) configured in accordance with embodiments of the present technology. The system 800 can be generally similar to the system 200 of FIG. 2. For example, the system 800 includes a carrier wafer 810, a coating 820 deposited on the carrier wafer 810, and a device wafer 830 attached to the coating 820. The coating 820 can be disposed between the carrier wafer 810 and the device wafer 830, and can include a plurality of layers including a first electrode layer 822, a second electrode layer 826, a dielectric layer 824 therebetween, and optionally a heat-absorbing layer 828. In some embodiments, the coating 820 can further include one or more dielectric layers (e.g., the first dielectric layer 221, the second dielectric layer 227) coupled to the carrier wafer 810 and/or the device wafer 830.

Also, a voltage source 850 can be electrically coupled to select layers of the coating 820 via a first lead 852 extending from the negative terminal of the voltage source 850 and a second lead 854 extending from the positive terminal of the voltage source 850. In the illustrated embodiment, the first lead 852 is electrically coupled to the first electrode layer 822 and the second lead 854 is electrically coupled to the second electrode layer 826. The first lead 852 can also be coupled to ground.

In operation, the voltage source 850 can be operated to apply a bias voltage to the first electrode layer 822 and the second electrode layer 826, and application of the bias voltage can cause breakdown of the dielectric layer 824. The dielectric layer 824 can have one or more features that facilitate the breakdown. In some embodiments, the dielectric layer 824 can have defects. For example, the dielectric layer 824 can include low-temperature deposited SiO₂, low-temperature deposited SiN, and/or carbon-doped oxides and nitrides. Such compositions can lead to the formation of various types of dielectric defects. In some embodiments, the dielectric layer 824 can include a 2D dielectric material (e.g., extremely thin) that has a low dielectric strength.

As discussed above with respect to FIG. 7, the breakdown of the dielectric layer 824 can generate heat. The heat-absorbing layer 828 can confine the heat generated by the breakdown of the dielectric layer 824 to the side of the heat-absorbing layer 828 with the MIM capacitor (e.g., the first electrode layer 822, the second electrode layer 826, and the dielectric layer 824 therebetween), and prevent (or at least impede) heat transfer to the device wafer 830.

The continuous breakdown of the dielectric layer 824 across the MIM capacitor surface area can lead to delamination between the first electrode layer 822 and the second electrode layer 826. Therefore the device wafer 830 (and the heat-absorbing layer 828 and the second electrode layer 826 bonded thereto) and the carrier wafer 810 (and the first electrode layer 822 bonded thereto) can be separated. One or more of the layers 722, 726, 728 can be subsequently scrubbed or otherwise removed, or kept thereon. In some embodiments, the voltage source 850 is electrically coupled to the coating 820 only once the system 800 is ready for this debonding step.

Referring to FIGS. 7 and 8 together, in some embodiments, the voltage applied to the electrode layers of the coating can be reduced by (i) separately raising the temperature of the system (e.g., to about 300° C.) using, for example, backside infrared (IR) light heating, (ii) reducing the thickness of the dielectric layer, and/or (iii) including defects in the dielectric layer, as discussed above. In some embodiments, multiple MIM capacitors (e.g., including the first and second electrode layers and the dielectric layer therebetween) can be patterned across the device wafer and/or the carrier wafer to individually release the interface between the wafers. Contact pads for the MIM capacitors can be placed across non-active areas along edge exclusions of the system. In some embodiments, the backside contacts can be exposed as illustrated schematically in FIG. 2.

By using the debonding process in accordance with embodiments of the present technology, the device wafer, and thus the rest of the semiconductor device manufactured, can be made free of the carrier wafer without the need to destructively remove the carrier wafer. By keeping the carrier wafer during the debonding process, the carrier wafer can be reused in the manufacture of additional semiconductor devices. This can directly result in material, process, and associated cost savings. In some cases, device wafers can include remnants of the debonding process, such as remnants of the heat-absorbing layer, traces of burnout regions on the heat-absorbing layer due to the breakdown of the dielectric layer, traces of metallic elements used as the electrode layers, etc. New, custom, or otherwise specialized equipment may be used to apply the bias voltage, separate the device wafer from the carrier wafer, and/or perform other steps of the debonding process described herein.

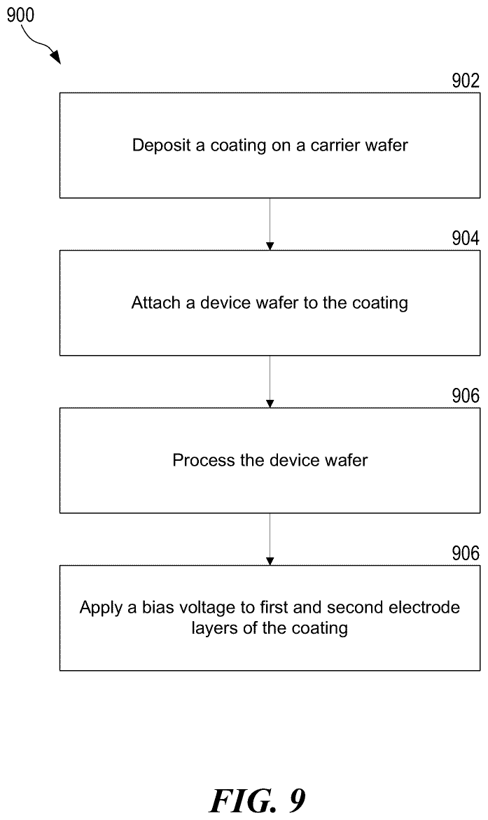

FIG. 9 is a flowchart illustrating a method for manufacturing a semiconductor device in accordance with embodiments of the present technology. While the steps of the method 900 are described below in a particular order, one or more of the steps can be performed in a different order or omitted, and the method 900 can include additional and/or alternative steps. Additionally, although the method 900 may be described below with reference to the embodiments of the present technology described herein, the method 900 can be performed with other embodiments of the present technology.

The method 900 begins at block 902 by depositing a coating on a carrier wafer. The coating can include a first electrode layer, a second electrode layer, and a dielectric or metal oxide layer between the first and second electrode layers. The first electrode layer can comprise at least one of tungsten, titanium nitride, or titanium. The second electrode layer comprises at least one of tungsten, ruthenium, or carbon. The metal oxide layer comprises at least one of titanium dioxide, cerium dioxide, zirconium dioxide, hafnium dioxide, or hafnium silicate. In some embodiments, depositing the coating on the carrier wafer comprises forming each of the first electrode layer, the second electrode layer, and the metal oxide layer via atomic layer deposition (ALD) and/or other type of suitable deposition method. In some embodiments, the coating further includes a sacrificial layer and/or a heat-absorbing layer.

In some embodiments, the metal oxide layer comprises a first metal oxide layer, and the coating further includes a second metal oxide layer disposed between the second electrode layer and the first metal oxide layer. The second metal oxide layer can be configured to impede growth of conductive suboxide filaments from reaching the second electrode layer. The second metal oxide layer can comprise at least one of aluminum oxide or magnesium oxide. In some embodiments, the coating further includes a first dielectric layer disposed between the first electrode layer and the carrier wafer and/or a second dielectric layer disposed over the second electrode layer.

At block 904, the method 900 continues by attaching a device wafer to the coating. In some embodiments, the device wafer is attached to the coating via dielectric-dielectric bonding and/or other type of suitable bonding.

At block 906, the method 900 continues by processing the device wafer. In some embodiments, the device wafer undergoes various wafer processing steps including thinning, backside processing, patterning and etching, implantation and doping, and/or the like. In some embodiments, one or more device layers are formed (e.g., deposited) on the side of the device wafer opposite the carrier wafer.

At block 908, the method 900 continues by applying a bias voltage to the first and second electrode layers. In some embodiments, applying the bias voltage can comprise separating the second electrode layer from the metal oxide layer, thereby separating the device wafer from the carrier wafer. More specifically, applying the bias voltage can comprise (i) reducing a portion of the metal oxide layer at a first interface between the first electrode layer and the metal oxide layer to generate oxide ions, (ii) migrating the oxide ions from the first interface to a second interface between the second electrode layer and the metal oxide layer, and (iii) oxidizing the oxide ions at the second interface to generate oxygen gas, wherein the oxygen gas causes separation of the second electrode layer from the metal oxide layer.

In some embodiments, applying the bias voltage can comprise breaking down the dielectric or metal oxide layer and melting the sacrificial layer away using heat generated from breaking down the metal oxide layer, thereby separating the device wafer from the carrier wafer. In some embodiments, applying the bias voltage can comprise breaking down the dielectric or metal oxide layer, thereby separating the device wafer from the carrier wafer. In some embodiments, applying the bias voltage comprises accessing the first and second electrode layers at a back side of the carrier wafer opposite the device wafer (see FIG. 2). In some embodiments, applying the bias voltage comprises accessing the first and second electrode layers at a front side of the carrier wafer through the device wafer (see FIG. 3).

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.” As used herein, including in the claims, “substantially” or “about” shall be construed to mean within plus or minus 10% of the recited numerical value.

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

I/We claim:

1. A method comprising:
depositing a coating on a carrier wafer, wherein the coating includes a first electrode layer, a second electrode layer, and a metal oxide layer between the first and second electrode layers;
attaching a device wafer to the coating;
processing the device wafer; and
applying a bias voltage to the first and second electrode layers, wherein applying the bias voltage separates the device wafer from the carrier wafer.

2. The method of claim 1, wherein applying the bias voltage comprises separating the second electrode layer from the metal oxide layer.

3. The method of claim 1, wherein applying the bias voltage comprises:
reducing a portion of the metal oxide layer at a first interface between the first electrode layer and the metal oxide layer to generate oxide ions;
migrating the oxide ions from the first interface to a second interface between the second electrode layer and the metal oxide layer; and
oxidizing the oxide ions at the second interface to generate oxygen gas, wherein the oxygen gas causes separation of the second electrode layer from the metal oxide layer.

4. The method of claim 1, wherein applying the bias voltage comprises accessing the first and second electrode layers at a back side of the carrier wafer opposite the device wafer.

5. The method of claim 1, wherein applying the bias voltage comprises accessing the first and second electrode layers at a front side of the carrier wafer through the device wafer.

6. The method of claim 1, wherein the first electrode layer comprises at least one of tungsten, titanium nitride, or titanium, and wherein the second electrode layer comprises at least one of tungsten, ruthenium, or carbon.

7. The method of claim 1, wherein the metal oxide layer comprises at least one of titanium dioxide, cerium dioxide, zirconium dioxide, hafnium dioxide, or hafnium silicate.

8. The method of claim 1, wherein the metal oxide layer comprises a first metal oxide layer, wherein the coating further includes a second metal oxide layer disposed between the second electrode layer and the first metal oxide layer, wherein the second metal oxide layer is configured to impede growth of conductive suboxide filaments from reaching the second electrode layer.

9. The method of claim 8, wherein the second metal oxide layer comprises at least one of aluminum oxide or magnesium oxide.

10. The method of claim 1, wherein the coating further includes a dielectric layer disposed either between the first electrode layer and the carrier wafer or over the second electrode layer.

11. The method of claim 1, wherein the coating further includes a sacrificial layer, and wherein applying the bias voltage comprises:
breaking down the metal oxide layer; and
melting, using heat generated from breaking down the metal oxide layer, the sacrificial layer to separate the device wafer from the carrier wafer.

12. The method of claim 1, wherein applying the bias voltage comprises breaking down the metal oxide layer to separate the device wafer from the carrier wafer.

13. A semiconductor device, comprising:
a device wafer; and
a portion of an electrode layer disposed on the device wafer, wherein the portion of the electrode layer comprises a part of a coating, wherein the coating is configured to be deposited on a carrier wafer, and wherein the device wafer is configured to be attached to the coating during manufacturing of the semiconductor device.

14. The semiconductor device of claim 13, further comprising one or more through-silicon vias (TSVs) extending at least partially through the device wafer.

15. The semiconductor device of claim 13, wherein the portion of the electrode layer comprises remnants of the electrode layer after a removal process for removing the electrode layer from the device wafer.

16. The semiconductor device of claim 13, wherein the portion of the electrode layer comprises the part of the coating separated from a metal oxide layer of the coating via formation of oxygen gas between the electrode layer and the metal oxide layer.

17. A semiconductor device manufacturing system, the system comprising:
a carrier wafer;
a coating deposited on the carrier wafer, wherein the coating includes:
a first electrode layer;
a second electrode layer; and
a metal oxide layer between the first and second electrode layers; and
a device wafer attached to the coating,
wherein the device wafer is configured to separate from the carrier wafer upon application of a bias voltage to the first and second electrode layers.

18. The system of claim 17, wherein the second electrode layer is configured to separate from the metal oxide layer upon application of the bias voltage to the first and second electrode layers, thereby separating the device wafer from the carrier wafer.

19. The system of claim 17, wherein application of the bias voltage is configured to:
reduce a portion of the metal oxide layer at a first interface between the first electrode layer and the metal oxide layer to generate oxide ions;
migrate the oxide ions from the first interface to a second interface between the second electrode layer and the metal oxide layer; and
oxidize the oxide ions at the second interface to generate oxygen gas, wherein the oxygen gas is configured to separate the second electrode layer from the metal oxide layer.

20. The system of claim 17, wherein the coating further comprises a sacrificial layer configured to be melted by heat generated from application of the bias voltage to the first and second electrode layers, thereby separating the device wafer from the carrier wafer.
